(19) United States
(12) Patent Application Publication
(10) Pub. No.: US 2025/0290818 A1
(43) Pub. Date: Sep. 18, 2025

(54) REPLACEMENT SIGNALING SEAL

(71) Applicant: LAM RESEARCH CORPORATION, Fremont, CA (US)

(72) Inventors: Jeremy TUCKER, Mountain View, CA (US); Karl Frederick LEESER, West Linn, OR (US); Dennis HAUSMANN, Lake Oswego, OR (US)

(21) Appl. No.: 18/859,868

(22) PCT Filed: May 12, 2023
(86) PCT No.: PCT/US2023/021985

§ 371 Date: Oct. 24, 2024

Related U.S. Application Data
(60) Provisional application No. 63/343,779, filed on May 19, 2022.

(51) Int. Cl. G01M 3/04; G01N 21/3504; G01N 21/62; H01L 21/683

(52) U.S. Cl. CPC G01M 3/04; G01N 21/3504; G01N 21/62; H01L 21/6833

(57) ABSTRACT

A seal for a substrate processing system includes a body comprised of a base material, an outer surface, and a marker material disposed at least one of throughout the base material within the body of the seal, in an outer edge region of the seal, in a coating disposed on the outer surface of the seal, and in an interior region of the seal. The marker material is different from the base material.

### CROSS-REFERENCE TO RELATED APPLICATIONS

This application claims the benefit of U.S. Provisional Application No. 63/343,779 filed on May 19, 2022. The entire disclosure of the above application is incorporated herein by reference.

### FIELD

The present disclosure relates to seals for substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to perform substrate treatment such as deposition or etching of film on a substrate such as a semiconductor wafer. Substrate processing systems typically comprise a processing chamber with a substrate support (such as a pedestal, a plate, etc.) arranged therein. The substrate support may comprise an electrostatic chuck (ESC). The substrate is arranged on the substrate support during treatment.

During substrate treatment such as etching, chemical vapor deposition (CVD), atomic layer deposition (ALD), atomic layer etching (ALE), a remote plasma clean (RCP) process, etc., gas mixtures may be introduced into the processing chamber using a gas diffusion device, such as a showerhead. Radio frequency (RF) plasma may be used during processing to activate chemical reactions.

### SUMMARY

A seal for a substrate processing system includes a body comprised of a base material, an outer surface, and a marker material disposed at least one of throughout the base material within the body of the seal, in an outer edge region of the seal, in a coating disposed on the outer surface of the seal, and in an interior region of the seal. The marker material is different from the base material.

In other features, the base material comprises a perfluoroelastomer and the marker material does not comprise any of fluorine, carbon, and a combination of fluorine and carbon. The marker material does not comprise any materials used during processing performed in the substrate processing system. The marker material is disposed throughout the base material within the body of the seal and the outer edge region of the seal does not comprise the marker material. A concentration of the marker material through the body of the seal varies as a radial distance from a center of the body of the seal varies. The outer edge region of the seal comprises the marker material and the interior region of the seal does not comprise the marker material. The marker material is configured to at least one of react with a material present during processing performed within the substrate processing system to generate a detectable byproduct and react with a component of ambient air to indicate a leak.

A system to determine whether to replace a seal in a substrate processing system includes a detection device to detect an amount of a marker material shed from the seal and a wear analyzation module to determine, based on the detected amount of the marker material shed from the seal, at least one of a cumulative amount of the marker material shed from the seal and an amount of wear of the seal, and, based on the at least one of the cumulative amount of marker material and the amount of wear of the seal, selectively output a signal that indicates that the seal should be replaced.

In other features, the detection device is an infrared detection device arranged to detect the marker material in at least one of gases within a processing chamber of the substrate processing system and gases exhausted from the processing chamber. The detection device is a residual gas analyzer arranged to detect the marker material in at least one of gases within a processing chamber of the substrate processing system and gases exhausted from the processing chamber. The detection device is an optical emission spectroscopy device arranged to detect the marker material in at least one of gases within a processing chamber of the substrate processing system and gases exhausted from the processing chamber.

In other features, the wear analyzation module determines the cumulative amount of the marker material shed from the seal and outputs the signal in response to the cumulative amount of the marker material exceeding a threshold. The wear analyzation module determines the cumulative amount of the marker material shed from the seal, determines the amount of wear of the seal based on the cumulative amount of the marker material, and outputs the signal in response to the determined amount of wear exceeding a threshold. The wear analyzation module outputs the signal in response to one of any amount of the marker material being detected and an amount of the marker material being detected exceeding a failure threshold. The wear analyzation module outputs the signal in response to the detected amount of the marker material decreasing below a threshold.

A method to determine whether to replace a seal in a substrate processing system includes detecting an amount of a marker material shed from the seal, determining, based on the detected amount of the marker material shed from the seal, at least one of a cumulative amount of the marker material shed from the seal and an amount of wear of the seal, and, based on the at least one of the cumulative amount of marker material and the amount of wear of the seal, selectively outputting a signal that indicates that the seal should be replaced.

In other features, the method further includes detecting the marker material in at least one of gases within a processing chamber of the substrate processing system and gases exhausted from the processing chamber. Detecting the marker material includes detecting the marker material using at least one of an infrared detection device, a residual gas analyzer, and an optical emission spectroscopy device. The method further includes determining the cumulative amount of the marker material shed from the seal and outputting the signal in response to the cumulative amount of the marker material exceeding a threshold. The method further includes determining the cumulative amount of the marker material shed from the seal, determining the amount of wear of the seal based on the cumulative amount of the marker material, and outputting the signal in response to the determined amount of wear exceeding a threshold.

In other features, the method further includes one of outputting the signal in response to any amount of the marker material being detected and outputting the signal in response to the detected amount of the marker material decreasing below a threshold. The method further includes forming the seal with the marker material by one of diffusing the marker material into the seal, implanting the marker material into the seal, and co-molding the seal with the marker material.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows a functional block diagram of an example of a substrate processing system comprising a processing chamber;

FIG. 2A shows example seals according to the present disclosure arranged between portions of a gas delivery conduit and around a stem of a showerhead;

FIG. 2B shows example seals according to the present disclosure arranged around a bond layer between a baseplate and a ceramic layer of a substrate support;

FIGS. 3A, 3B, 3C, 3D, and 3E show cross-sections of example seals according to the present disclosure;

FIG. 4 is a functional block diagram of an example detection system according to the present disclosure; and

FIG. 5 illustrates steps of an example method for indicating and detecting whether a seal according to the present disclosure should be replaced.

In the drawings, reference numbers may be reused to identify similar and/or identical elements.

### DETAILED DESCRIPTION

A substrate processing system comprises various elastomeric seals to maintain a desired pressure (e.g., a vacuum pressure) within a processing chamber, prevent leaking of gas mixtures between separate chambers/volumes and into atmosphere, protect components from exposure to plasma, etc.

For example, a substrate support may comprise one or more edge seals configured to protect a bonding layer or other portions of the substrate support from exposure to plasma. A gas distribution device such as a showerhead may comprise one or more seals or O-rings configured to prevent leaking of gas mixtures outside of the processing chamber. Similarly, various gas lines, channels, valves, etc. configured to supply gas mixtures or plasma (e.g., in a remote plasma system) to the processing chamber and exhaust gas supply mixtures from the processing chamber comprise respective seals to prevent leaking of the gas mixtures into atmosphere.

Over time, the seals degrade due to exposure to plasma (e.g., fluorine and/or oxygen plasma), corrosive gas mixtures, and high temperatures. Accordingly, seals eventually fail and need to be replaced. In some examples, seals are periodically replaced (e.g., in accordance with a preventative maintenance schedule. Maintenance schedules may be determined based on best estimates of component lifetime.

Typically, estimates of component lifetime are conservative to minimize the risk of failure during operation. Accordingly, seals may ultimately be replaced long before any actual risk of failure, which may result in unnecessary down time and premature replacement of expensive seals.

Seals and methods according to the present disclosure are configured to indicate when a seal is approaching failure. In this manner, seals can be replaced prior to actual failure but without being replaced while the seal still has significant remaining lifetime. In other words, premature replacement of the seals is minimized.

As one example, the seal contains a marker or dopant material that is detectable in-situ (e.g., within the processing chamber, gas supply or exhaust lines, etc.). In other words, as the seal wears over time, the marker material sheds from the seal and becomes detectable within the volume of the processing chamber and in gas mixtures exhausted from the processing chamber. The marker material may be an element, a compound, etc. The marker material may be a polymer comprising a nitrile/cyano functional group, hydrogen sulfide and/or a polymer comprising hydrogen sulfide, and/or a noble gas.

A detection system (e.g., an in-situ infrared detection system) is configured to detect the marker material in gases within and/or exhausted from the processing chamber. For example, some substrate processing systems comprise a detection system configured to detect concentrations of various materials in process gases exhausted from the processing chamber. The detection system may be tuned to detect a specific material. As one example, the detection system may be tuned to detect an amount of silicon tetrafluoride (SiF₄) in an exhaust flow during a remote plasma clean process. The remote plasma clean process may be stopped when the amount of silicon tetrafluoride decreases below a threshold that indicates that the processing chamber is sufficiently clean. The detection system may be retuned (e.g., periodically, for some period during each process, etc.) to detect the marker material emitted from the seal. Detected amounts of the marker material that exceed a threshold indicate that the seal should be replaced.

In another example, some substrate processing systems use a residual gas analyzer. The residual gas analyzer may be configured to detect the marker material according to the principles of the present disclosure. In still other examples, optical emission spectroscopy may be used to detect the marker material.

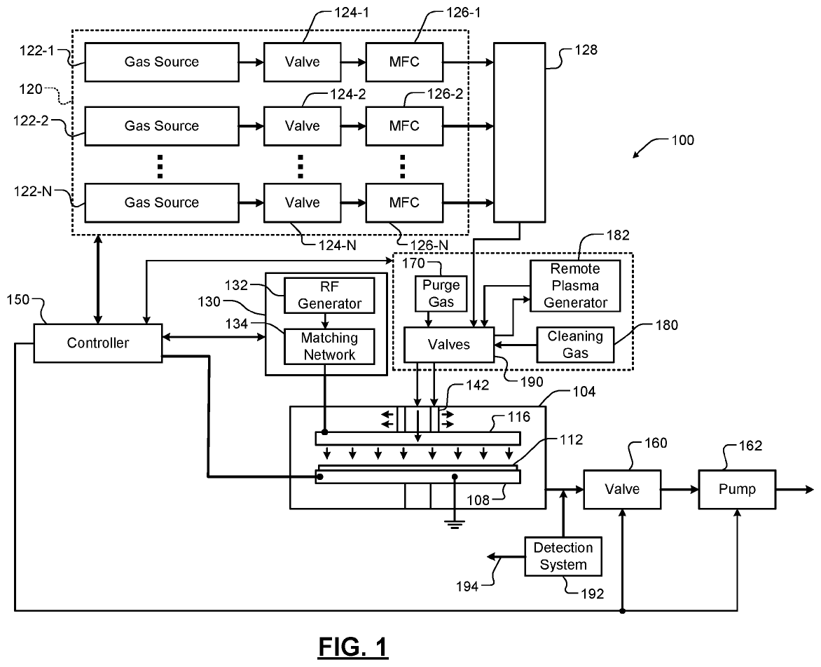

FIG. 1 shows an example of a substrate processing system 100 including a processing chamber 104. A substrate support (e.g., a pedestal) 108 is arranged within the processing chamber 104. A substrate 112 is arranged on the substrate support 108 during processing. A gas distribution device such as a showerhead 116 is arranged in the processing chamber 104 above the substrate support 108.

A gas delivery system 120 comprises gas sources 122-1, 122-2, . . . , and 122-N (collectively gas sources 122) that are connected to valves 124-1, 124-2, . . . , and 124-N (collectively valves 124) and mass flow controllers 126-1, 126-2, . . . , and 126-N (collectively MFCs 126). The MFCs 126 control flow of gases from the gas sources 122 to a manifold 128 where the gases mix. An output of the manifold 128 is supplied to the showerhead 116. The showerhead 116 comprises an internal plenum and gas through-holes. The showerhead 116 introduces and distributes process gases via the gas through-holes into the processing chamber 104.

An RF generating system 130 generates and outputs an RF voltage to the showerhead 116 or the substrate support 108 (the other is DC grounded, AC grounded or floating). For example only, the RF generating system 130 may comprise an RF voltage generator 132 that generates the RF voltage that is fed by a matching network 134 to the showerhead 116 or the substrate support 108. Plasma is generated when process gases and RF power are supplied to the showerhead 116.

In some examples, while processing the substrate 112 (e.g., during ALD cycles), an inert gas such as argon (Ar) or molecular nitrogen (N₂) may be used as a primary purge gas flowing through the showerhead 116 in purging steps. Molecular oxygen (O₂) or molecular nitrogen (N₂) may also be used as a purge gas to prevent or minimize any undesirable deposition at remote areas such as the backside of the showerhead 116 and the walls and the top plate of the processing chamber 104.

A controller 150 controls the flow of process gases, monitors process parameters such as temperature, pressure, power, etc., and controls striking and extinguishing plasma, removal of reactants, etc. The controller 150 controls gas delivery from the gas delivery system 120 to supply process and/or purge gases at set intervals during a process. The controller 150 controls pressure in the processing chamber 104 and/or evacuation of reactants using the valve 160 and the pump 162. The controller 150 controls the temperature of the substrate support 108 and the substrate 112 based on temperature feedback from sensors (not shown) in the substrate support 108 and/or sensors (not shown) measuring coolant temperature. A purge gas source 170 and a corresponding valve may be used by the controller 150 to selectively supply the secondary purge gas.

In some examples, the substrate processing system 100 comprises a cleaning gas source 180 and a remote plasma generator 182. For example, the remote plasma generator 182 may comprise an inductively coupled plasma (ICP) chamber that generates plasma when the cleaning gas source 180 supplies a cleaning gas. Accordingly, the remote plasma generator 182 may be referred to as a remote plasma clean generator. Plasma generated by the remote plasma generator 182 may be referred to as a pre-activated cleaning gas and/or a remote plasma clean (RPC) gas. The controller 150 controls the supply of the cleaning gas from the cleaning gas source 180 and, in some examples, the supply of the pre-activated cleaning gas from the remote plasma generator 182 to clean the processing chamber 104.

The substrate processing system 100 further comprises a plurality of valves 190 to allow delivery of process and purge gases during substrate processing and to allow delivery of the pre-activated cleaning gas, an inert gas, and the cleaning gas during chamber cleaning. The controller 150 controls the valves 190 to supply appropriate process and purge gases to the processing chamber 104 while processing the substrate 112. The controller 150 controls the valves 190 to supply other suitable gases to the processing chamber 104 while cleaning the processing chamber 104. A combination or sub-combination of elements 120, 128, 170, 180, 190 may be collectively called a gas supply system. In some implementations, the gas supply system may comprise element 150 and/or element 182.

The substrate processing system 100 comprises various seals (not shown in FIG. 1) arranged within and/or between various components and sealed volumes, such as within gas lines, channels, and valves of the gas supply system, between the gas supply system and the processing chamber 104, between the processing chamber 104 and atmosphere, between components within the processing chamber 104 and a processing volume (i.e., plasma within the processing chamber 104), etc.

Seals in the substrate processing system 100 according to the present disclosure are configured to indicate when a seal is approaching failure as describe below in more detail. For example, one or more seals contain a marker or dopant material that is detectable in gases exhausted from the processing chamber 104 as the seal wears over time.

A detection system 192 is configured to detect the marker material in gases within and/or exhausted from the processing chamber 104. Although shown between the processing chamber 104 and the valve 160, the detection system 192 may be arranged in other locations throughout the substrate processing system 100. For example, all or portions of the detection system 192 may be located downstream of the valve 160 and/or the pump 162, on or within the processing chamber 104, etc. The detection system 192 may be an infrared detection system, a residual gas analyzer, etc. tuned to detect the marker material in gases exhausted from the processing chamber 104. The detection system 192 outputs a signal 194 based on the detected marker material. For example, the detection system 192 outputs the signal 194 to the controller 150, a display (not shown in FIG. 1), etc.

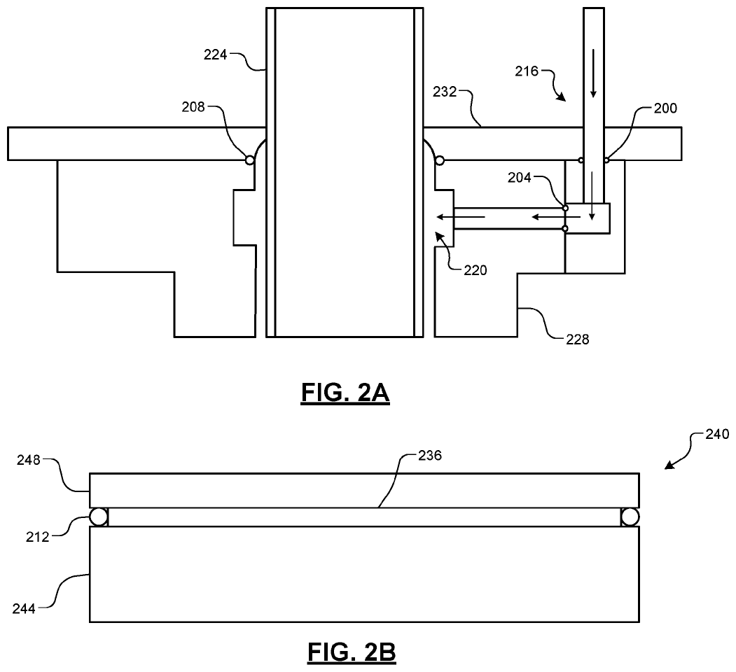

FIGS. 2A and 2B show example seals 200, 204, 208, and 212 that may be configured to indicate wear according to the present disclosure. As shown in FIG. 2A, the seals 200 and 204 are arranged between portions of a gas delivery conduit 216. For example, the gas delivery conduit 216 supplies purge and/or cleaning gas mixtures to a channel 220 defined between a stem 224 of a showerhead (e.g., the showerhead 116 of FIG. 1) and a collar 228. For example, the collar 228 is configured to attach the stem 224 to a lid 232 of the processing chamber 104. In other examples, the gas delivery conduit 216 supplies gas mixtures through the stem 224. The seals 200 and 204 are arranged between the lid 232 and the collar 228, between separate portions of the collar 228, etc. The seal 208 is arranged between the collar 228 and the lid 232 around the stem 224.

Conversely, the seal 212 is arranged around a bonding layer 236 of a substrate support 240. For example, the bonding layer 236 is arranged between a baseplate 244 and a ceramic layer 248 of the substrate support 240. The seal 212 surrounds the bonding layer 236 and protects the bonding layer 236 from exposure to plasma and other process gases within the processing chamber 104.

The seals 200, 204, 208, and 212 are each exposed to various purge, cleaning, and/or process gases and high temperatures. Over time, the seals 200, 204, 208 and 212 degrade and eventually need to be replaced. The seals 200, 204, 208, and 212 according to the present disclosure are configured to indicate when a seal is approaching failure. The arrangements of the seals 200, 204, 208, and 212 are shown only as examples and the principles of the present disclosure may be implemented using seals in any location within the substrate processing system 100.

One or more of the seals 200, 204, 208, and 212 (e.g., the seal 200) according to the present disclosure contains a marker or dopant material that is detectable in gases exhausted from the processing chamber 104. In other words, as the seal 200 wears over time, the marker material sheds from the seal 200. The detection system 192 is configured to detect the marker material in gas mixtures within the processing chamber 104 and/or exhausted from the processing chamber 104.

In some examples, different seals may comprise different marker materials. In this manner, the detection system 192 may be configured to detect which seal is shedding a detected marker material. The marker material is selected in accordance with a base material of the seal 200 and materials that may be typically used within the substrate processing system 100. For example, the marker material is specifically selected to be different from the base material of the seal 200 and materials that may be typically used within the substrate processing system 100. In other words, the marker material will only be detected in response to being shed from the seal and will not be inadvertently detected in gas mixtures used or otherwise present during processing, purging, cleaning, etc. As one example, if the process being performed is an RPC process with an SiF4 byproduct, the marker material does not include SiF4.

As one example, the seal 200 is an elastomeric seal comprising a perfluoroelastomer (e.g., an FFKM perfluoroelastomer) and may comprise both fluorine and carbon. The marker material may be nonreactive or minimally reactive to components of the substrate processing system 100, substrates, and materials used in gas mixtures supplied to the substrate processing system 100. In other examples, the marker material may be inherently reactive or volatile and/or react with process gases to generate a volatile byproduct to facilitate detection by optical emission spectroscopy, mass spectrometry, Fourier transform infrared (FTIR) detection, etc. In one example, the marker material may be configured to react with a component of air (e.g., oxygen and/or nitrogen) to generate a detectable byproduct. In this manner, if a leak of ambient air into the substrate processing system 100 is present, detection of the byproduct of the reaction between the marker material and the ambient air is indicative of the leak and the need to replace the seal 200.

As one example, the marker material is generally uniformly distributed throughout the body of the seal 200. In other words, the marker material is distributed throughout the base material of the seal 200. In another example, the marker material is only distributed throughout an interior region of the seal 200 and is not present at or near an outer surface of the seal 200. Accordingly, none of the marker material is initially shed from the seal 200. Rather, over time, the outer surface of the seal 200 erodes without shedding the marker material. When a portion of the interior of the seal 200 becomes exposed (i.e., subsequent to the outer surface wearing away), the marker material is shed and can then be detected. In another example, an outer layer or coating that does not comprise the marker material is disposed on the seal 200. Subsequent to the coating wearing away, the marker material is exposed and shed and becomes detectable.

In still another example, an interior of the seal 200 does not comprise the marker material. Instead, only an outer surface, a radially outer edge region adjacent to and/or including the outer surface, a coating disposed on the outer surface of the seal 200, etc. comprises the marker material. In an example implementation, the marker material is initially shed from the seal and is detectable by the detection system 192. As the outer surface or coating wears away over time, less of the marker material may be shed. In other words, in some examples, an amount of the marker material decreasing below a threshold may be indicate that the seal 200 should be replaced.

The detection system 192 is configured to indicate that the detected amount of the marker material exceeds a threshold. For example, the detection system 192 determines whether the detected amount of the marker material exceeds a threshold, decreases below a threshold, etc., and selectively outputs a signal (e.g., to a display) indicating that the seal should be replaced.

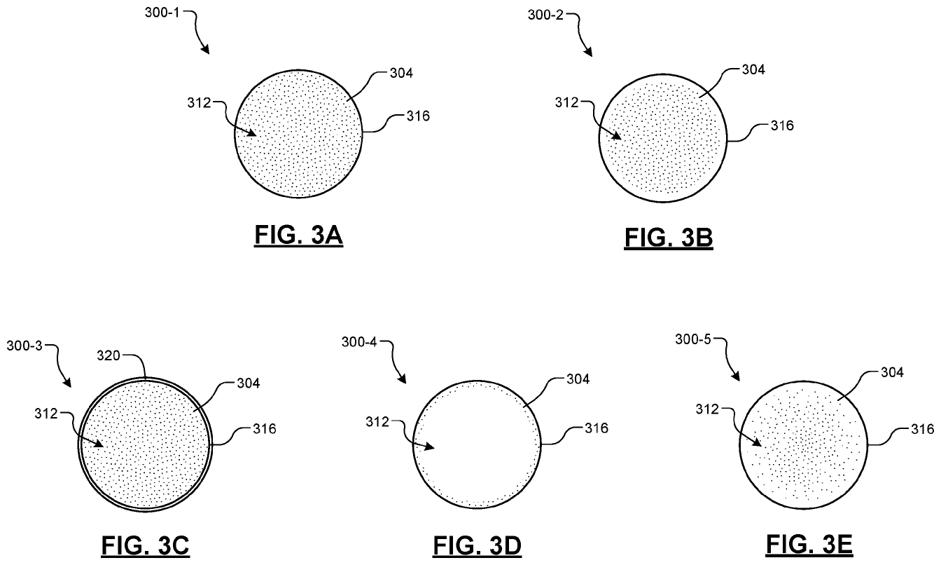

Various processes may be used to form the seal 200 with the marker material. In one example, the marker material is diffused into the base material of the seal. For example, the base material is exposed to a dopant in a diffusion furnace. In another example, the marker material is directly injected or implanted into the base material. In still another example (e.g., the examples shown in FIGS. 3B and 3C), a co-molding process is used to form the seal 200 including the marker material. Formation of the seal 200 including the marker material is not limited to these example processes and other suitable processes may be used.

FIGS. 3A, 3B, 3C, 3D, and 3E show cross-sections of example seals 300-1, 300-2, 300-3, 300-4, and 300-5 (referred to collectively as seals 300) according to the principles of the present disclosure. The seals 300 may be used in any of the locations shown in FIGS. 2A and 2B (i.e., corresponding to any of the seals 200, 204, 208, and 212) and/or in any other location throughout the substrate processing system 100. Although shown as having a generally circular cross-section (e.g., as an O-ring), the seals 300 may have other suitable shapes.

As shown in FIG. 3A, a marker material 304 is generally uniformly distributed throughout a body of the seal 300-1. In other words, the marker material 304 is distributed throughout a base material 312 of the seal 300. As shown in FIG. 3B, the marker material 304 is only distributed throughout an interior of the seal 300-2 and is not present at or near an outer surface 316 of the seal 300-2.

As shown in FIG. 3C, the marker material 304 is generally uniformly distributed throughout the body of the seal 300-3. A coating 320 that does not comprise the marker material 304 is disposed on the outer surface 316 of the seal 300-3. As shown in FIG. 3D, an interior of the seal 300-4 does not comprise the marker material 304. Instead, only the outer surface 316 of the seal 300-4 comprises the marker material 304.

In other examples, the marker material 304 may be non-uniformly distributed throughout the body of the seal 300 in another manner. For example, as shown in FIG. 3E, the marker material 304 varies as a radial distance from a center of the body of the seal 300-5 varies. As shown, the concentration of the marker material 304 increases as a distance from the outer surface 316 increases. In other words, the concentration of the marker material 304 increases in a direction toward the center of the seal 300-5. In other examples, the concentration of the marker material 304 decreases in a direction toward the center of the seal 300-5. Accordingly, as the seal 300-5 wears over time, the amount of marker material 304 detected in a given sample may increase or decrease.

FIG. 4 is a functional block diagram of an example detection system 400 (e.g., corresponding to the detection system 192) according to the present disclosure. Components of the detection system 400 may be implemented in one or more controllers (e.g., the controller 150). In some examples, the detection system 400 may comprise one or more processers configured to execute instructions stored in memory.

The detection system 400 comprises a detection device 404 arranged and configured to detect the marker material in gases 408 exhausted from the processing chamber 104. For example, the detection device 404 may comprises an infrared detection device, a residual gas analyzer, an emission spectroscopy device, or another device configured to detect material within gas mixtures. In one example, all or a portion of the detection device 404 is arranged within an exhaust stream containing the gases 408. For example, the detection device 404 is arranged within an exhaust pipe or conduit configured to exhaust the gases 408 from the processing chamber 104. In other examples, the detection device 404 is arranged to capture an image of the gases 408 (e.g., through a window or other opening). In still other examples, the detection device 404 (e.g., implemented as a residual gas analyzer) is configured to receive or capture a portion of the gases 408.

The detection device 404 may be selectively adjusted to detect concentrations of specific materials in process gases exhausted from the processing chamber 104. In other words, the detection device 404 may be tuned to detected different materials at different times. As one example, the detection device 404 may be tuned (e.g., responsive to a wear analyzation module 412) to detect the marker material. In other examples, the detection device 404 may be tuned to always detect the marker material (i.e., during all processing and cleaning performed in the processing chamber 104).

The detection device 404 outputs a detection signal indicative of the detected marker material to the wear analyzation module 412. For example, the detection signal may identify an amount (e.g., a concentration, percentage, etc.) of the marker material detected in the gases 408. The wear analyzation module 412 is configured to calculate an amount of wear of the seal (e.g., any of the seals 300) based on the detection signal. For example, the wear analyzation module 412 may receive the detection signal continuously or periodically.

The wear analyzation module 412 calculates and updates a cumulative wear value based on individual samples of the detected amount of the marker material. For example, the wear analyzation module 412 may correlate a cumulative amount of the marker material detected with a wear amount (e.g., a wear percentage) of the seal 300. When the wear amount of the seal 300 or the cumulative amount of the detected marker material exceeds a threshold, the wear analyzation module 412 selectively outputs a signal (e.g., to a display 416) indicating that the seal 300 should be replaced.

As described in examples 3A-3D above, the wear analyzation module 412 may be configured to indicate that the seal 300 should be replaced depending on the specific configuration of the seal 300. For example, the wear analyzation module 412 may be configured to indicate that the seal 300-1 should be replaced when the cumulative detected amount exceeds a threshold. The wear analyzation module 412 may be configured to indicate that the seal 300-2 or 300-3 should be replaced when any marker material is detected. The wear analyzation module 412 may be configured to indicate that the seal 300-4 should be replaced when the detected amount of the marker material in a given sample is below a threshold.

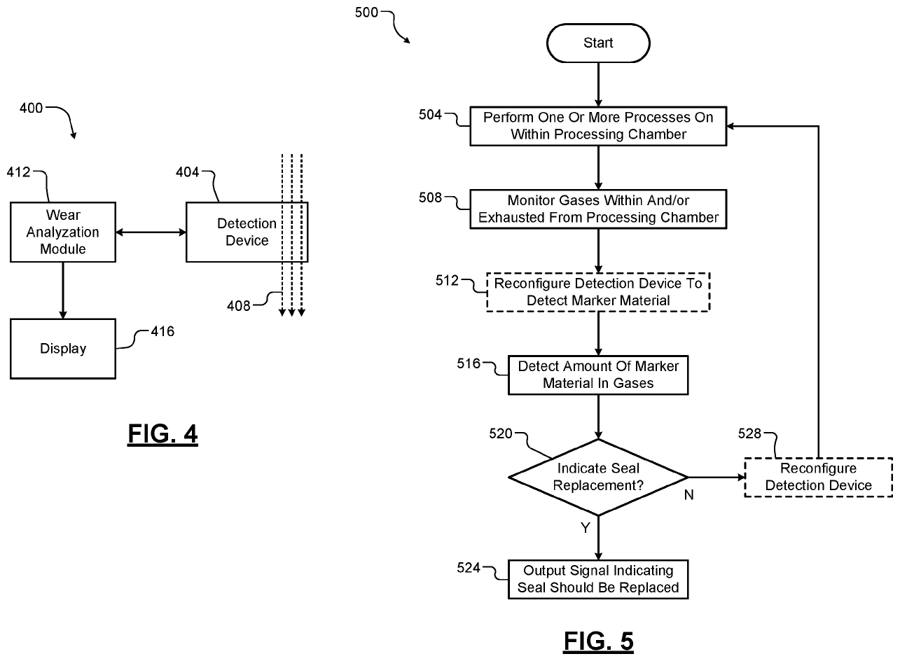

FIG. 5 illustrates steps of an example method 500 for indicating and detecting whether a seal according to the present disclosure should be replaced. At 504, the method 500 (e.g., the substrate processing system 100) performs one or more processes within a processing chamber. The processes may include, but are not limited to, processes performed on a substrate arranged in the processing chamber and a cleaning process (e.g., a remote plasma clean process).

At 508, the method 500 (e.g., the detection system 400) monitors gases within and/or exhausted from the processing chamber. For example, the detection system 400 may be configured to monitor the gases continuously or periodically during processing, monitor gases exhausted from the processing chamber, only during a remote plasma clean process, etc.

At 512, the method 500 (e.g., the detection system 400) optionally reconfigures the detection device 404 to detect the marker material. For example, in some systems, the detection device 404 may be normally configured to detect other materials, such as materials cleaned from the processing chamber. Accordingly, the detection device 404 may be periodically (e.g., once per cleaning cycle) reconfigured to detect the marker material. In other examples, the detection device 404 may always be configured to detect the marker material. In still other examples, the detection device 404 may be configured to detect multiple types of materials.

At 516, the method 500 (e.g., the detection device 404) detects the amount of marker material in the monitored gases. For example, the detection device 404 outputs a detection signal indicative of the amount of the marker material in the gases to the wear analyzation module 412.

At 520, the method 500 (e.g., the wear analyzation module 412) determines whether to indicate that the seal should be replaced based on the detection signal. For example, the wear analyzation module 412 calculates a cumulative amount of marker material detected, an amount of wear of the seal, etc. and determines whether the calculated amount exceeds a corresponding threshold. If true, the method 500 proceeds to 524. If false, the method 500 proceeds to 528.

In other examples, the detection signal may indicate a large increase in the amount of marker material detected. For example, the amount of marker material detected may be generally constant (e.g., within a percentage) during a lifetime of the seal 300. However, a failure event caused by excessive compression or other stress (due to time, temperature, etc.) may cause a large increase in the amount of marker material detected. Accordingly, the wear analyzation module 412 may additionally determine whether the detected amount of the marker material exceeds failure event threshold. For example, the failure event threshold may be greater than (e.g., 150% or more than) an average amount of marker material detected per sample over the lifetime of the seal 300.

At 524, the method 500 selectively outputs a signal indicating that the seal should be replaced. For example, the wear analyzation module 412 outputs the signal to the display 416, which may be configured to display a recommendation to a user to replace the seal. The method 500 then proceeds to 528.

At 528, the method 500 (e.g., the detection system 400) optionally reconfigures the detection device 404. For example, if the detection device 404 was reconfigured at 512 to detect the marker material, the detection device 404 may be returned to a configuration for detecting other materials.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A seal for a substrate processing system, the seal comprising:
a body comprised of a base material;
an outer surface; and
a marker material disposed at least one of (i) throughout the base material within the body, (ii) in an outer edge region of the seal, (iii) in a coating disposed on the outer surface, and (iv) in an interior region of the seal,
wherein the marker material is different from the base material.

2. The seal of claim 1, wherein the base material comprises a perfluoroelastomer and the marker material does not comprise any of fluorine, carbon, and a combination of fluorine and carbon.

3. The seal of claim 2, wherein the marker material does not comprise materials used during processing performed in the substrate processing system.

4. The seal of claim 1, wherein one of (i) the marker material is disposed throughout the base material within the body of the seal and the outer edge region of the seal does not comprise the marker material and (ii) a concentration of the marker material through the body of the seal varies as a radial distance from a center of the body of the seal varies.

5. The seal of claim 1, wherein the outer edge region of the seal comprises the marker material and the interior region of the seal does not comprise the marker material.

6. The seal of claim 1, wherein the marker material is configured to at least one of (i) react with a material present during processing performed within the substrate processing system to generate a detectable byproduct and (i) react with a component of ambient air to indicate a leak.

7. A system to determine whether to replace a seal in a substrate processing system, the system comprising:
a detection device to detect an amount of a marker material shed from the seal; and
a wear analyzation module to
determine, based on the detected amount of the marker material shed from the seal, at least one of (i) a cumulative amount of the marker material shed from the seal and (ii) an amount of wear of the seal, and
based on the at least one of the cumulative amount of marker material and the amount of wear of the seal, selectively output a signal that indicates that the seal should be replaced.

8. The system of claim 7, wherein the detection device is an infrared detection device arranged to detect the marker material in at least one of (i) gases within a processing chamber of the substrate processing system and (ii) gases exhausted from the processing chamber.

9. The system of claim 7, wherein the detection device is a residual gas analyzer arranged to detect the marker material in at least one of (i) gases within a processing chamber of the substrate processing system and (ii) gases exhausted from the processing chamber.

10. The system of claim 7, wherein the detection device is an optical emission spectroscopy device arranged to detect the marker material in at least one of (i) gases within a processing chamber of the substrate processing system and (ii) gases exhausted from the processing chamber.

11. The system of claim 7, wherein the wear analyzation module determines the cumulative amount of the marker material shed from the seal and outputs the signal in response to the cumulative amount of the marker material exceeding a threshold.

12. The system of claim 7, wherein the wear analyzation module determines the cumulative amount of the marker material shed from the seal, determines the amount of wear of the seal based on the cumulative amount of the marker material, and outputs the signal in response to the determined amount of wear exceeding a threshold.

13. The system of claim 7, wherein the wear analyzation module outputs the signal in response to one of (i) any amount of the marker material being detected and (ii) an amount of the marker material being detected exceeding a failure threshold.

14. The system of claim 7, wherein the wear analyzation module outputs the signal in response to the detected amount of the marker material decreasing below a threshold.

15. A method to determine whether to replace a seal in a substrate processing system, the method comprising:
detecting an amount of a marker material shed from the seal;
determining, based on the detected amount of the marker material shed from the seal, at least one of (i) a cumulative amount of the marker material shed from the seal and (ii) an amount of wear of the seal; and
based on the at least one of the cumulative amount of marker material and the amount of wear of the seal, selectively outputting a signal that indicates that the seal should be replaced.

16. The method of claim 15, further comprising detecting the marker material in at least one of (i) gases within a processing chamber of the substrate processing system and (ii) gases exhausted from the processing chamber.

17. The method of claim 16, wherein detecting the marker material comprises detecting the marker material using at least one of an infrared detection device, a residual gas analyzer, and an optical emission spectroscopy device.

18. The method of claim 15, further comprising determining the cumulative amount of the marker material shed from the seal and outputting the signal in response to the cumulative amount of the marker material exceeding a threshold.

19. The method of claim 15, further comprising determining the cumulative amount of the marker material shed from the seal, determining the amount of wear of the seal based on the cumulative amount of the marker material, and outputting the signal in response to the determined amount of wear exceeding a threshold.

20. The method of claim 15, further comprising one of (i) outputting the signal in response to any amount of the marker material being detected and (ii) outputting the signal in response to the detected amount of the marker material decreasing below a threshold.

21. The method of claim 15, further comprising forming the seal with the marker material by one of (i) diffusing the marker material into the seal, (ii) implanting the marker material into the seal, and (iii) co-molding the seal with the marker material.
